(19) United States
(12) Patent Application Publication
(10) Pub. No.: US 2015/0349510 A1
(43) Pub. Date: Dec. 3, 2015

(54) REVERSE BLOCKING APPARATUS FOR ELECTRONIC DEVICE AND SWITCH APPARATUS INCLUDING THE SAME

(71) Applicant: SKYWORKS SOLUTIONS, INC., Woburn, MA (US)

(72) Inventor: Hua PENG, Shanghai (CN)

(73) Assignee: SKYWORKS SOLUTIONS, INC., Woburn, MA (US)

(21) Appl. No.: 14/287,256

(22) Filed: May 27, 2014

(51) Int. Cl. H02H 3/00; H03F 1/52; H03F 3/21; H05B 33/08

(52) U.S. Cl. CPC H02H 3/003; H05B 33/0815; H03F 1/523; H03F 3/21; H03F 2200/462

(57) ABSTRACT

Reverse blocking apparatus for electronic devices and switch apparatus including the same. In some embodiments, a blocking system for an electronic device can include a determining unit configured to generate an indication signal indicative of a condition associated with an undesirable current in the electronic device. Such an undesirable current can be a reverse current which can damage electronic devices such as transistors. The blocking system can further include a blocking unit in communication with the determining unit. The blocking unit can be configured to be coupled to a terminal of the electronic device. The blocking unit can be further configured to inhibit or reduce passage of the undesirable current in the electronic device based on the indication signal. Examples of applications of such a blocking system and related methods are disclosed.

### TECHNICAL FIELD

The technical solution relates to electronic technology field, and more particularly, to a reverse blocking apparatus for an electronic device, a switch apparatus including the reverse blocking apparatus and a method for blocking a reverse voltage and a reverse current in the electronic device.

### BACKGROUND

In a course of using a conventional electronic device, typically only voltage and current in a single direction are allowed. For example, in an ideal diode, only voltage and current from anode to cathode are allowed, and voltage and current from the cathode to the anode typically do not exist. In an N-type Mental Oxide Semiconductor (NMOS) triode, when a high voltage is applied to a gate electrode of the NMOS triode, a conductive channel between a drain electrode and a source electrode is established in the NMOS triode correspondingly; when a voltage is applied to the drain electrode, a corresponding voltage will appear on the source electrode. If a closed loop circuit is formed, a corresponding current from the drain electrode to the source electrode will flow through the conductive channel. Similarly, since the conductive channel has been established, when the voltage is applied to the source electrode, a corresponding voltage will appear on the drain electrode, and a corresponding current will be generated after the circuit is closed. When a low voltage is applied to the gate electrode of the NMOS triode, since the conductive channel has not been established yet, even if the voltage is applied to the drain electrode or the source electrode, no voltage will be generated on the source electrode or the drain electrode, and no corresponding current will appear even if the circuit is closed.

Due to production process, operating conditions of the electronic device and the like, a reverse voltage and a reverse current may exist when the electronic device works. In the diode, a reverse voltage flowing from a cathode to anode may be present under some temperature and maximum reverse voltage condition; and the higher the temperature is, the greater the reverse current is typically; the lower the temperature is, the smaller the reverse current is typically. When the reverse current increases to a certain value, the diode may be penetrated and damaged thereby. In the triode, in the case that the conductive channel is not established, the reverse current may exist, which will be described below in connection with FIG. 1.

FIG. 1 schematically shows a structure diagram of an NMOS triode having a parasitic diode. The NMOS triode has a gate electrode G, a drain electrode D and a source electrode S. In the NMOS triode made of silicon-based material, due to the fabrication process, typically a parasitic diode PD exists between the drain electrode D and the source electrode S. For example, in the case that the source electrode S of the NMOS triode is connected to the substrate, as shown in FIG. 1, the source electrode S is the anode of the parasitic diode PD, and the drain electrode D is the cathode of the parasitic diode PD. When the gate electrode G of the NMOS triode is at a high voltage, a conductive channel is established between the drain electrode D and the source electrode S. When a voltage is applied to the drain electrode, a corresponding voltage may appear on the source electrode in order to turn on the NMOS triode, and a forward current from the drain electrode D to the source electrode S may be present in the NMOS triode. When the gate electrode G of the NMOS triode is at a low voltage, the conductive channel is not established between the drain electrode D and the source electrode S (e.g., when the NMOS triode is turned off), but a PN junction exists between the gate electrode G and the drain electrode D of the NMOS triode. The PN junction is just the parasitic diode PD as shown in FIG. 1. At this time, if the voltage on the source electrode S of the NMOS triode is higher than the voltage on its drain electrode D, the parasitic diode PD may be turned on, and thus a reverse current from the source electrode S to the drain electrode D may be generated. The reverse current may affect the drain voltage and the source voltage of the NMOS triode. Similarly, a parasitic diode may also exist in a PMOS triode. When the gate electrode G of the PMOS triode is at a high voltage in order to turn off the PMOS triode, if a voltage exists on the drain electrode and the source electrode of the PMOS triode, the parasitic diode may be turned on, and thus a reverse current from the drain electrode to the source electrode is generated.

According to the above description, it is known that the reverse current in the electronic device may damage the electronic device per se, and may also affect normal operation of the electronic device. Thus, it is a safety risk that may impair the application module for the application system, so it is necessary or desirable to block the reverse voltage and the reverse current of the electronic device. In the conventional diode, the reverse current can be appropriately controlled by controlling the anode voltage, which, however, cannot effectively block the reverse current, especially when the temperature is high, or the cathode voltage of the diode is high. As for the NMOS triode or PMOS triode, during the fabrication process of the triode, there may be another parasitic diode connected back to back with the parasitic diode by controlling the substrate voltage of the triode, in order to block the reverse current. However, the conventional triode is typically a triode without a function of blocking the reverse current, and the reverse current will remain. Therefore, an effective solution is urgently necessary or desirable to block the reverse current of the electronic device, in order to ensure the normal operation of the electronic device and protect the electronic device per se.

### SUMMARY

Various aspects of the present application may relate to a reverse blocking apparatus for an electronic device, a switch apparatus including the reverse blocking apparatus and a method for blocking a reverse current in the electronic device.

The reverse blocking apparatus for the electronic device according to the embodiment of the present application may be applied to any electronic device having a reverse current from an output terminal to an input terminal under some conditions, for example, a diode, a triode, an electronic component including a plurality of electronic elements, etc. The reverse blocking apparatus for the electronic device may comprise a reverse determining unit and a reverse blocking unit. The reverse determining unit determines whether the electronic device satisfies a condition of having a reverse current, and outputs an indication signal for indicating whether the electronic device is capable of having a reverse current. The reverse blocking unit connects with the output terminal of the electronic device, and is for connecting the electronic device to a load thereof or blocking the connection of the electronic device with the load thereof based on the indication signal.

In the case of implementing the reverse blocking unit by a switch, the switch may be, for example, a triode, which correspondingly also has a parasitic diode therein. The affection of the parasitic diode in the switch may be removed by setting a direction of the triode in the switch (e.g., the connection relationship between the source electrode and the drain electrode).

The reverse blocking unit according to the embodiment of the present application may block a reverse signal in the switch apparatus. The switch apparatus according to an embodiment of the present application may comprise a first switch and a second switch. The first switch has an input terminal which receives a first voltage V1, has an output terminal which is connected to a load module, and is closed or opened under a control of a first enable signal. The second switch has an input terminal which receives a second voltage V2, has an output terminal which is connected to the load module, and is closed or opened under a control of a second enable signal. If the second voltage V2 is greater than the first voltage V1, the switch apparatus may further comprise a first reverse determining unit and a third switch. The first reverse determining unit determines whether the first switch satisfies a condition of having a reverse current, and outputs a first indication signal for indicating whether the first switch is capable of having a reverse current or not. The third switch connects in series to the output terminal of the first switch, is used for connecting the first switch to a load module or blocking the connection of the first switch with the load module based on the first indication signal. The first reverse determining unit may determine whether the first switch satisfies the condition of having the reverse current or not based on the first enable signal, and output the first indication signal. If the first voltage V1 is greater than the second voltage V2, the switch apparatus may further comprise a second reverse determining unit and a fourth switch. The second reverse determining unit is for determining whether the second switch satisfies the condition of having a reverse current, and outputting a second indication signal for indicating whether the second switch is capable of having a reverse current or not. The fourth switch connects in series to the output terminal of the second switch, and is used for connecting the second switch with the load module or blocking a connection of the second switch with the load module based on the second indication signal. The second reverse determining unit may determine whether the second switch satisfies the condition of having the reverse current or not based on the second enable signal, and output the second indication signal.

In various embodiments of the present application, by of the foregoing examples of connecting the reverse blocking apparatus to the output terminal of the electronic device, the reverse current and the reverse voltage in the electronic device may be effectively blocked, in order to ensure normal operation of the electronic device and protect the electronic device per se. Furthermore, the reverse blocking apparatus may block the reverse current and reverse voltage in the electronic device by an ordinary triode. The solution is simple and of low cost.

### BRIEF DESCRIPTION OF THE DRAWINGS

In order to more clearly illustrate technical solutions, the drawings referenced in the description of embodiments or conventional technologies will be briefly introduced below. The drawings described below are only some embodiments of the present invention, and other drawings can also be obtained by those ordinarily skilled in the art according to these drawings. Throughout the drawings, the same reference sign typically refer to the same part.

FIG. 1 schematically shows a structure diagram of a conventional NMOS triode having a parasitic diode.

FIG. 2 schematically shows a block diagram of a reverse blocking apparatus for an electronic device according to an embodiment of the present application.

FIG. 3 shows a schematic connection structure when a reverse-circuit blocking unit of FIG. 2 is a NMOS triode.

FIG. 4 schematically shows an application example of a conventional switch apparatus.

FIG. 5 schematically shows a structure diagram of a switch apparatus including a reverse blocking apparatus according to an embodiment of the present application.

FIG. 6(a) and FIG. 6(b) show the measurement results of the operation of a switch apparatus 500 in FIG. 5.

FIG. 7 schematically shows a flowchart of a method for blocking a reverse signal in the electronic device according to an embodiment of the present application.

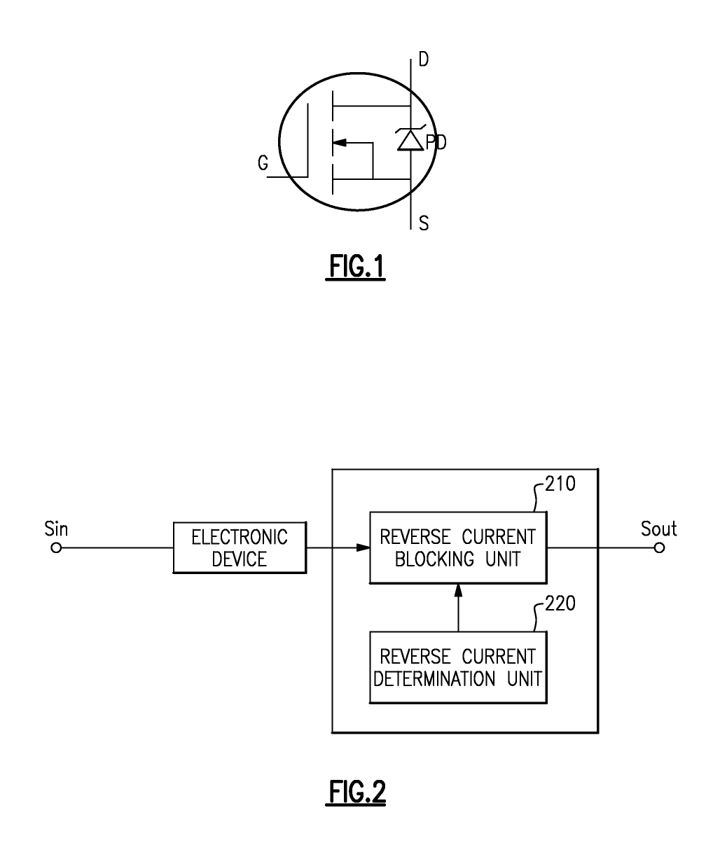

### DETAILED DESCRIPTION

Below, the technical solutions in the embodiments of the present application will be described in conjunction with the accompanying drawings in the embodiments of the present application. The described embodiments are generally part of, but not all of the embodiments of the present application. In the case of no conflict, the embodiments of the present application and the features of the embodiments may be arbitrarily combined with each other.

Electronic Device to which Reverse Blocking Apparatus is Applied

A reverse blocking apparatus according to the embodiment of the present application may be applied to any electronic device having a reverse current, which includes but not limited to, a diode, various types of triodes. The triode is, for example, an NMOS triode, a PMOS triode, a TMOS triode, a vertical-channel metal oxide semiconductor (VMOS) triode, a transition metal oxide semiconductor (TMOS) triode and the like. Alternatively, the electronic device may be an electronic component including a plurality of electronic elements, which collaborate to implement certain functions. An output signal from an output terminal of the electronic device may connect to a load, which may be any circuit, e.g., a triode, an electronic die, an electronic circuit, an electronic module, etc. Since the electronic device may have a plurality of output terminals, unless a definite contrary indication is provided, all the output terminals hereinafter refer to the output terminal of the electronic device that may generate a reverse current.

In a normal operation state, the electronic device may have a forward current from an input terminal to an output terminal, but not have a reverse current from the output terminal to the input terminal, or the reverse current may be too small and negligible. Under some conditions, the electronic device may generate the reverse current from the output terminal to the input terminal, and the reverse current will affect the operation of the electronic device. Hereinafter, the cases that the electronic device does not have the reverse current, and that the reverse current is very small and negligible are generally called as that the electronic device does not have the reverse current; the electronic device having the reverse current includes a case that the reverse current affects the operation of the electronic device so that it cannot be ignored. The conditions where electronic device is capable of having a reverse current are different for various electronic devices.

Reverse Blocking Apparatus of the Present Application

FIG. 2 schematically shows a block diagram of a reverse blocking apparatus 200 for an electronic device according to an embodiment of the present application. The electronic device to which the reverse blocking apparatus 200 is applied is an electronic device that may have a reverse current from the output terminal (e.g., Sout in FIG. 2) to the input terminal (e.g., Sin in FIG. 2) under a specific condition, which, as described above, may be a diode, a triode, an electronic component including a plurality of electronic elements and the like. The specific type and structure of the electronic device does not constitute a limitation to the embodiments of the present application, as long as it possibly has a reverse current.

As shown in FIG. 2, the electronic device connected to the load thereof via a reverse blocking apparatus according to the embodiment of the present application, the reverse blocking apparatus 200 may include a reverse determining unit 210 and a reverse blocking unit 220. The reverse determining unit 210 determines whether the electronic device satisfies the condition of having a reverse current, and outputs an indication signal for indicating whether the electronic device is capable of having a reverse current. The reverse blocking unit 220 is connected to the output terminal of the electronic device, and is for connecting the electronic device with a load thereof or blocking the connection of the electronic device with the load thereof based on the indication signal.

In accordance with different electronic devices, the reverse determining unit 210 may determine whether the electronic device satisfies the condition of having the reverse current by utilizing one or more different modes. Specifically, the reverse determining unit 210 may determine whether the electronic device has a reverse current based on a predetermined condition that the reverse current is generated in the electronic device.

Taking the electronic device being a diode as an example, if both terminals of the diode have a maximum reverse voltage, it can be determined that the diode is capable of having a reverse current. The maximum reverse voltage is a maximum voltage from the cathode to the anode that can be withstood by the diode; when the reverse voltage from the cathode to the anode of the diode exceeds the maximum reverse voltage, the diode will be damaged. Further, the reverse current from the cathode to the anode of the diode not only depends on the reverse voltage thereof, but also on the temperature of the diode. Specifically, in a case that the diode has the maximum reverse voltage, the higher the temperature of the diode is, the greater the reverse current is; the lower the temperature of the diode is, the smaller the reverse current is. Thus, the reverse determining unit 210 may determine whether the diode satisfies the condition of having the reverse current according to at least one of the reverse voltage and the temperature of the diode, and output an indication signal for indicating whether the diode is capable of having a reverse current. Specifically, the reverse determining unit 210 can detect at least one of the reverse voltage and the temperature of the diode, determine or estimate the reverse current according to, for example, a relation table between the reverse voltage and the temperature of the diode and the reverse current thereof, and determine that the diode satisfies the condition of having the reverse current when the determined or estimated reverse current is greater than a preset current threshold value (e.g., 500 uA, 2 mA). The preset current threshold value can be set in advance as required or desired, which can vary with different types of diodes, or different requirements or designs.

In a case that the electronic device is a triode, with the NMOS triode as an example, when the gate electrode of the NMOS triode is supplied a low level driving signal so that the NMOS triode is turned off, if the source voltage of the NMOS triode is higher than the drain voltage thereof, a reverse current will be present in the NMOS triode. Therefore, the reverse determining unit 210 may determine whether the NMOS triode satisfies the condition of having a reverse current according to the operation state and the drain voltage of the NMOS triode, and output an indication signal for indicating whether the diode is capable of having a reverse current. Specifically, the reverse determining unit 210 may determine whether the NMOS triode is in an off state, determine whether the source-drain voltage is greater than zero when the NMOS triode is in the off state, determine that the NMOS triode satisfies the condition of having a reverse current when the source-drain voltage is greater than zero, and determine that the NMOS triode does not meet the condition of having a reverse current when the NMOS triode is not in the off state or the source-drain voltage is not greater than zero.

The reverse blocking unit 220 connects the electronic device with the load thereof or blocks the connection of the electronic device with the load thereof based on the indication signal. Specifically, the reverse blocking unit 220 may connect the electronic device with the load thereof, when the indication signal indicates that the electronic device is not capable of having a reverse current; and block the connection of the electronic device with the load thereof, when the indication signal indicates that the electronic device is capable of having a reverse current. Alternatively, the reverse blocking unit 220 may also block the connection of the electronic device with the load thereof in all the cases except that the electronic device is not capable of having the reverse current.

The reverse blocking unit 220 may be implemented by a switch. When the indication signal output by the reverse determining unit 210 indicates that the electronic device is not capable of having a reverse current, the switch closes in order to connect the electronic device with the load thereof, so that the output terminal of the electronic device can normally drive the load. When the indication signal indicates that the electronic device is capable of having the reverse current, the switch is open to block the connection of the electronic device with the load thereof, so that the input of the reverse voltage is blocked and the reverse current is removed, in order to prevent the reverse current from damaging the electronic device or affecting the normal operation of the electronic device. Alternatively, the reverse blocking unit 220 may be implemented by using a variable resistor. When the indication signal output by the reverse determining unit 210 indicates that the electronic device is not capable of having a reverse current, the variable resistor is controlled to have a minimum resistance value (e.g., 0 ohm), in order to connect the electronic device with the load thereof. When the indication signal indicates that electronic device is capable of having a reverse current, the variable resistor is controlled to have a maximum resistance value (e.g., 10 kilo-ohms), thus an open circuit is approximately formed between the electronic device and the load thereof to significantly reduce or eliminate the reverse current.

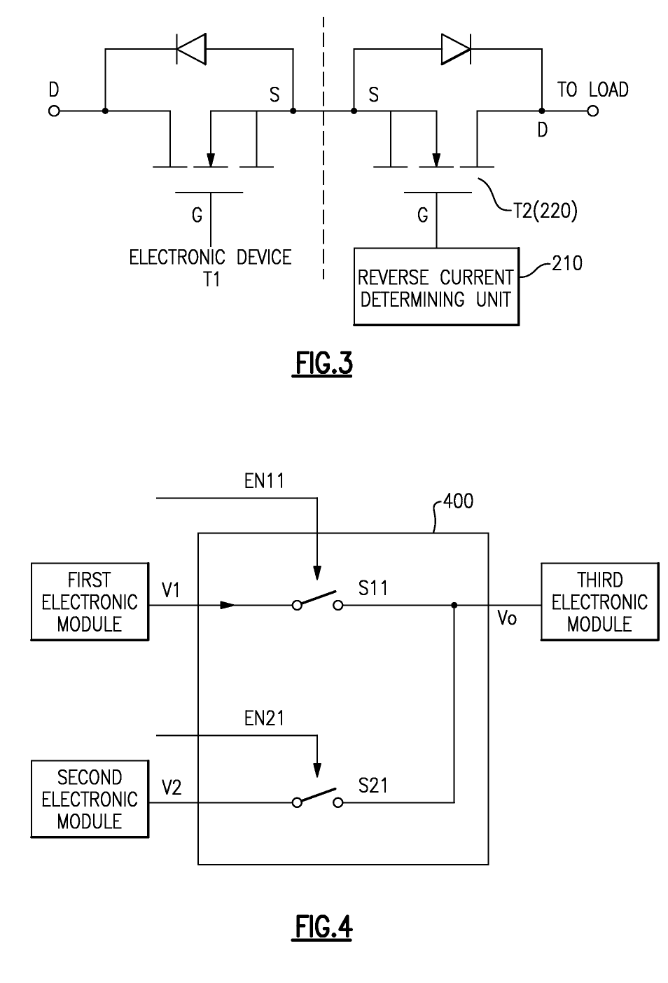

In the case of implementing the reverse blocking unit 220 by using the switch, the switch, for example, may be a triode, which correspondingly also has a parasitic diode therein, whose affection can be avoided by setting a direction of the triode in the switch (e.g., the connection between the source electrode and the drain electrode). Description will be made below in conjunction with FIG. 3.

FIG. 3 shows a schematic connection structure when a reverse blocking unit 220 of FIG. 2 is a NMOS triode. The reverse determining unit 210 in FIG. 3 is the same as that in FIG. 2, and the electronic device is illustrated as an NMOS triode T1, and an NMOS triode T2 is used as the reverse blocking unit 220 in FIG. 2. It can be seen from FIG. 3, the NMOS triode T2 and the NMOS triode T1 are connected back to back. That is, the source electrode of the NMOS triode T2 is connected to a source of an electronic device, i.e., the source electrode of the NMOS triodes T1; the drain electrode of the NMOS triode T2 is connected to the load of the electronic device. During normal operation of the NMOS triode T1 (i.e., the electronic device), the current flowing from the drain electrode to the source electrode (i.e., forward current) may be present in the NMOS triode T1. At this time, the reverse determining unit 210 outputs the indication signal indicating there is no condition associated with reverse current, and drives the gate electrode of the NMOS triode T2 to turn it on, in order to form a conducting circuit between the source electrode of the NMOS triode T1 (i.e., output terminal) and the load. When the NMOS triode T1 turns off and the voltage at the load port is greater than the drain voltage, the parasitic diode in the NMOS triode T1 enables presence of the reverse current from the source electrode to the drain electrode. At this time, the reverse determining unit 210 outputs the indication signal indicating there can be a reverse current, and drives the gate electrode of the NMOS triode T2 to turn it off. In addition, since the cathode of the parasitic diode of the NMOS triode T2 is connected to the load, no current flows therein, thereby the connection between the load port and the source electrode (i.e., the output terminal) of the NMOS triode T1 is further blocked, which effectively blocks the reverse current in the NMOS triode T1.

According to the above description in conjunction with FIG. 2 and FIG. 3, it is known that connecting the reverse blocking apparatus at the output terminal of the electronic device can effectively block the reverse current and the reverse voltage in the electronic device, in order to ensure normal operation of the electronic device and the protect the electronic device per se. Further, as shown in FIG. 3, an ordinary triode can be conveniently used to block the reverse current in the electronic device, and this solution is simple and of low cost.

Application of Reverse Blocking Apparatus in Switch Apparatus

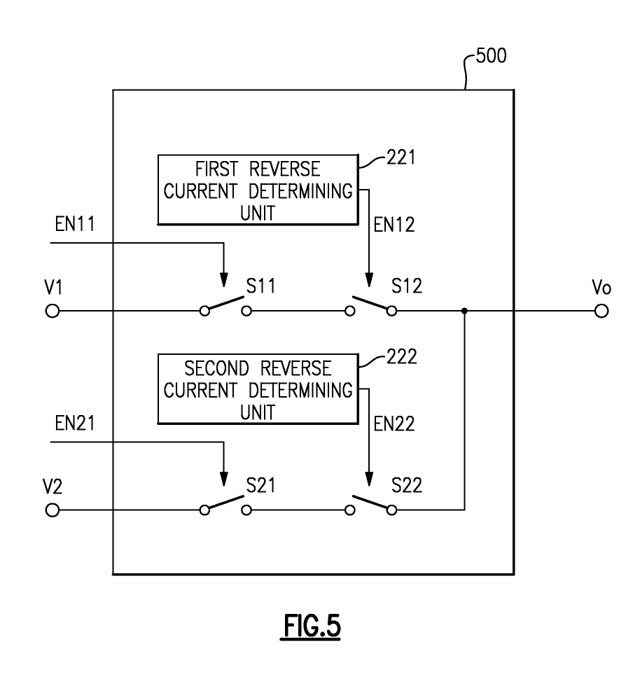

An application of the reverse blocking apparatus to a switch apparatus according to the embodiment of the present application is described below in conjunction with FIG. 4-FIG. 6.

FIG. 4 schematically shows an application example of a conventional switch apparatus. The switch apparatus 400 is used for providing at least one of an output voltage of a first electronic module and an output voltage of a second electronic module to a third electronic module.

As an example, the third electronic module may be a power amplifier in an electronic device, and the switch apparatus 400 may be used for providing different voltages to the power amplifier to control the gain thereof, thus the power amplifier can amplify an input signal into an output signal of different powers, so as to meet different needs. The first electronic module is, for example, an automatic power control module for outputting an automatically controlled power voltage Vacp. The second electronic module is, for example, a power administration integrated circuit, for outputting a power administration voltage Vpa. When the first switch S11 is closed and the second switch S21 is open, the switch apparatus 400 will provide an automatically controlled power voltage Vacp to the third electronic module; when the first switch S11 is open and second switch S21 is closed, the switch apparatus 400 provides the power administration voltage Vpa to the third electronic module.

Alternatively, the switch apparatus 400 may also be used for supplying power to each type of load module to be powered. In this case, the third electronic module may be any electronic module to be powered in the electronic device. The first electronic module may be a power module including a battery and a voltage converter, where the voltage converter converts a fixed DC voltage to a voltage that is utilized by the third electronic module to power the third electronic module. The second electronic module may be a power adapter, which converts an AC voltage to a voltage that is utilized by the third electronic module to power the third electronic module.

As shown in FIG. 4, the switch apparatus 400 includes a first switch S11 and a second switch S21. The first switch S11 has input terminal connected to the first electronic module, and has output terminal which is connected to the third electronic module, and is closed or opened under a control of a first enable signal EN11. The second switch S21 has input terminal connected to the second electronic module, has output terminal connected to the third electronic module, and is closed or open under the control of a second enable signal EN21. When the first switch S11 is closed and the second switch S21 is open, the switch apparatus 400 provides the voltage V1 output by the first electronic module to the third electronic module; when the first switch S11 is open and the second switch S21 is closed, the switch apparatus 400 provides the voltage V2 output by the second electronic module to the third electronic module.

In order to improve the switching speed of the switch apparatus 400, typically triodes can be used as the first switch S11 and the second switch S21. As described above, since the parasitic diode exists in the triode, a reverse current may be generated in the first switch S11 or the second switch S21, e.g., the reverse current may be present in the switch apparatus 400. Assume that the output voltage V1 of the first electronic module is 3 Volt, the output voltage V2 of the second electronic module is 1.5 Volt. When the triode serving as the first switch S11 turns off, and the triode serving as the second switch S21 turns on, the switch apparatus 400 provides the output voltage V2 of the second electronic module to the third electronic module, e.g., the output voltage of the switch apparatus 400 is Vo=V2=1.5 Volt. When the triode serving as the first switch S11 turns on and the triode serving as the second switch S11 turns off, the switch apparatus 400 provides the output voltage V1 of the first electronic module to the third electronic module, e.g., the output voltage of the switch apparatus 400 is Vo=V1=3 Volt. At this time, the output terminal voltage (3 Volt) of the triode serving as the second switch S21 is greater than the input terminal voltage thereof (1.5 Volt), and thus a reverse current can be present in the triode serving as the second switch S21. Therefore, a reverse current can be present in the conventional switch apparatus 400 shown in FIG. 4, which thereby affects normal operation of switch element (e.g., the triode) in the switch apparatus 400.

In the above case where V1 (3 Volt) is greater than V2 (1.5 Volt), the reverse current may be present in the second switch S21. Similarly, in the case where V1 is less than V2, the reverse current may be present in the first switch S11. If at least one of the output voltage V1 of the first electronic module and the output voltage V2 of the second electronic module is variable, the reverse current may be present in the first switch S11 and the second switch S21 of the switch apparatus 400.

FIG. 5 schematically shows a structure diagram of a switch apparatus 500 including a reverse blocking apparatus according to an embodiment of the present application. The first switch S11 and second switch S21 of the switch apparatus 500 in FIG. 5 can be the same as those in FIG. 4, which are no longer described here. The difference between the switch apparatus 500 in FIG. 5 and the switch apparatus 400 in FIG. 4 includes the switch apparatus 500 having a first reverse determining unit 221, a third switch S12, a second reverse determining unit 222, and a fourth switch S22. The first reverse determining unit 221 determines whether the first switch S11 meets the condition of having the reverse current, and outputs a first indication signal EN12 for indicating whether the first switch S11 is capable of having the reverse current or not. The third switch S12 connects in series to the output terminal of the first switch S11, and is used for connecting the first switch S11 with the load module (e.g., the third electronic module in FIG. 4) of the switch apparatus 500 or blocking the connection of the first switch S11 with the load module based on the first indication signal EN12. The second reverse determining unit 222 determines whether the second switch S21 satisfies the condition of having the reverse current, and outputs the second indication signal EN22 for indicating whether the second switch S21 is capable of having the reverse current or not. The fourth switch S22 connects in series to the output terminal of the second switch S21, and is used for connecting the second switch S21 with the load module or blocking the connection of the second switch S21 with the load module based on the second indication signal EN22.

The third switch S12 and the first reverse determining unit 221 in FIG. 5 constitute the reverse blocking apparatus for the first switch S11. The fourth switch S22 and the second reverse determining unit 222 in FIG. 5 constitute the reverse blocking apparatus for the second switch S21. It should be noted that in the switch apparatus 500 in FIG. 5, if the voltage V1 on the input terminal of the first switch S11 is constantly greater than the voltage V2 on the input terminal of the second switch S21, the reverse blocking apparatus for the first switch S11 in FIG. 5 may be omitted, i.e., the third switch S12 and the first reverse determining unit 221 may be omitted; if the voltage V1 on the first input terminal of the first switch Si 1 is constantly smaller than the second voltage V2 on the input terminal of the switch S21, then the reverse blocking apparatus for the second switch S21 in FIG. 5 may be omitted, i.e., the fourth switch S22 and the second reverse determination unit 222 may be omitted.

The content about the first reverse determining unit 221 and the third switch S12 may be referred to the above description in conjunction with FIG. 2 and FIG. 3. In the switch apparatus 500 of FIG. 5, the third switch S12 can be open or closed simultaneously with the first switch S11, in order to ensure either the input voltage V1 or V2 is provided to the load module. Accordingly, the first reverse determining unit 221 may generate the first indication signal EN12 based on the first enable signal EN11 for the first switch S11. When the first switch S11 and the third switch S12 are triodes of the same type (e.g., NMOS triodes or PMOS triodes), the first reverse determining unit 221 may take the first enable signal EN11 as the first indication signal EN12, and the first switch S11 and the third switch S12 are connected preferably in a back-to-back manner as shown in FIG. 3. When the first switch S11 is a NMOS triode, and the third switch S12 is a PMOS triode which is different type, the first reverse determining unit 221 may obtain the first indication signal EN12 by inversing the first enable signal EN11.

Similarly, the content on the second reverse determining unit 222 and the fourth switch S22 may also be referred to the above description in conjunction with FIG. 2 and FIG. 3. In the switch apparatus 500 of FIG. 5, the fourth switch S22 can be open or closed simultaneously with the second switch S21, in order to ensure either the input voltage V1 or V2 is provided to the load module. Accordingly, the second reverse determining unit 222 may generate the second indication signal EN22 based on the second enable signal EN21 used for the second switch S21. When the second switch S21 and the fourth switch 22 are triodes of the same type (e.g., NMOS triodes or PMOS triodes), the second reverse determining unit 222 may take the second enable signal EN21 as the second indication signal EN22, and the second switch S21 and the fourth switch S22 are connected preferably in a back-to-back manner as shown in FIG. 3. When the second switch S21 is a NMOS triode, and the fourth switch S22 is a PMOS triode (both switches are different types of triodes), the second reverse determining unit 222 may obtain the second indication signal EN21 by inversing the second enable signal EN22.

Either the third switch S12 or the fourth switch S22 can be implemented by utilizing technologies associated with any switch. When the third switch S12 or the fourth switch S22 is implemented by a triode, a connection manner of the triode T2 as shown in FIG. 3 is preferably adopted.

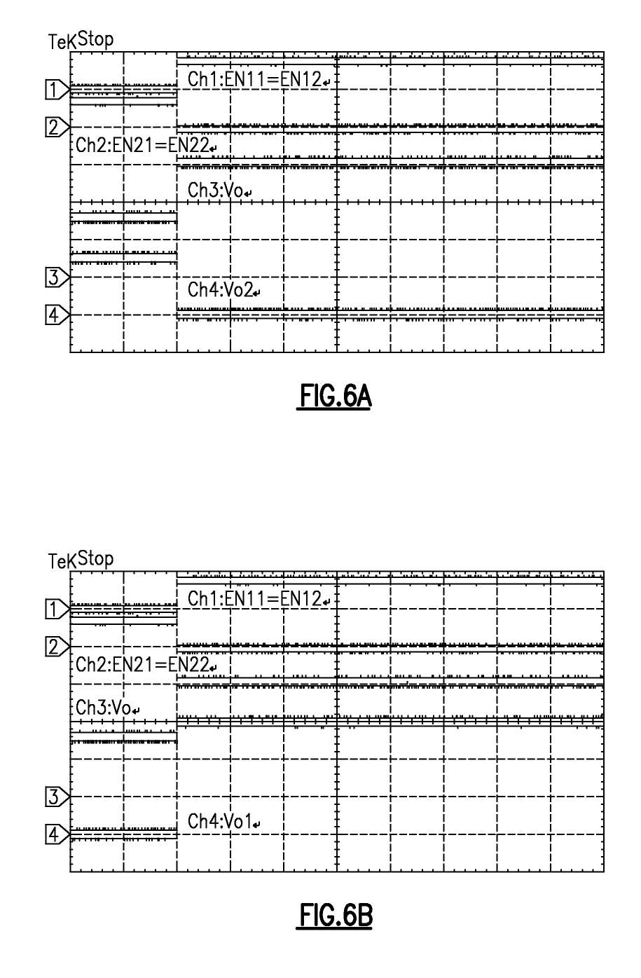

FIG. 6(a) and FIG. 6(b) show measurement results of the operation of a switch apparatus 500 in FIG. 5. In FIG. 6, switch apparatuses AAT4282A from Advanced Analogic Technologies Incorporated (AATI) are used as examples, with each switch apparatus AAT4282A including two metal oxide semiconductor field effect triodes (MOSFETs). Accordingly, two switch devices AAT4282A may be used to implement the switch apparatus 500 of FIG. 5, and two metal oxide semiconductor field effect triodes (MOSFETs) in one switch apparatus AAT4282A are connected back to back, which are respectively used as the first switch S11 and the third switch S12; and two MOSFETs in the other switch apparatus AAT4282A are connected back to back, which are respectively used as the second switch S21 and the fourth switch S22. The first switch S11 is provided an input voltage V1 of 3 volt, and the third switch S12 is provided an input voltage V2 of 1.5 volt.

In the measurement results of FIG. 6(a), the horizontal axis represents measurement time and the longitudinal axis represents a measured voltage, wherein the measured voltages of the four channels are shown by the numbers 1, 2, 3 and 4 on the longitudinal axis. Channel 1 (ch1) shows the first enable signal EN11 of the first switch S11, the first enable signal EN11 being equal to the first indication signal EN12 for the third switch S12; channel 2 (ch2) shows the second enable signal EN21 for the second switch S21, the second enable signal S22 being equal to the second indication signal EN22 for the fourth switch S21; Channel 3 (ch3) shows the output terminal voltage of the switch apparatus 500; Channel 4 (ch4) shows a voltage Vo2 on the connection point between the second switch S21 and the fourth switch S22. The positions of the numbers 1, 2, 3, and 4 on the longitudinal axis in FIG. 6(a) are respectively the zero value positions of the voltage signals of respective channels.

In the measurement results of FIG. 6(b), the horizontal axis represents measurement time and the longitudinal axis represents a measured voltage, wherein the measured voltages of the four channels are shown by the numbers 1, 2, 3, 4 on the longitudinal axis. The Channels 1-3 are respectively the same as the Channels 1-3 as shown in FIG. 6(a). Channel 4 (ch4) in FIG. 6(b) indicates a voltage Vo1 on the connection point between the first switch S11 and the third switch S12. The positions of the numbers 1, 2, 3, 4 on the longitudinal axis in FIG. 6(b) are respectively the zero value positions of the voltage signals of respective channels.

According to FIG. 6(a) and FIG. 6(b), it can be seen what are shown in the following Table 1. When EN11=EN12 is enabled (high level) and EN21=EN22 is disabled (low level), the first switch S11 and the third switch S12 are closed, the second switch S21 and the fourth switch S22 are open, the output voltage Vo of the switch apparatus 500 is equal to the input voltage V1, a voltage Vm2 on the connection point between the second switch S21 and the fourth switch S22 is 0, thereby the reverse current in the second switch S21 is well blocked; the voltage Vo1 on the connection point between the first switch S11 and the third switch S12 is equal to the input voltage V1, the third switch S12 does not affect the normal operation of the first switch S11. When EN11=EN12 is disabled (low level) and EN21=EN22 is enabled (high level), the first switch S11 and the third switch S12 are open, the second switch S21 and the fourth switch S22 are closed, the output voltage Vo of the switch apparatus 500 is equal to the input voltage V2, the voltage Vm2 on the connection point between the second switch S21 and the fourth switch S22 is also V2, the fourth switch S22 does not affect the normal operation of the second switch S21, the voltage Vo1 on the connection point between the first switch S11 and the third switch S12 is equal to 0, and the third switch S12 blocks the reverse current of the first switch S11. Therefore, the reverse current in the switch apparatus 500 is well blocked.

TABLE 1

| EN11 | EN12 | EN21 | EN22 | Vo | Vo2 | Vo1 |
|---|---|---|---|---|---|---|
| Enabled | Enabled | Disabled | Disabled | V1 | 0 | V1 |
| Disabled | Disabled | Enabled | Enabled | V2 | V2 | 0 |

According to the above description in conjunction with FIGS. 4-6, it is shown that the reverse current and the reverse voltage in the switch can be effectively blocked by connecting the reverse blocking apparatus at the output terminal of the switch, so as to ensure normal operation of the switch. Further, an ordinary triode can be conveniently used to block the reverse current in the switch, and this solution is simple and of low cost.

Method for Blocking Reverse Signal of Electronic Device According to the Embodiment of the Present Application

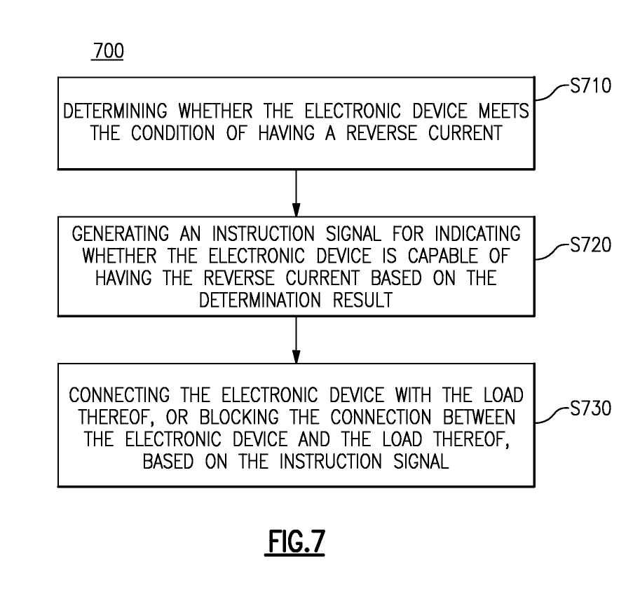

FIG. 7 schematically shows a flowchart of a method for blocking a reverse signal in the electronic device according to the embodiment of the present application. The method 700 for blocking a reverse signal of an electronic device may be applied to any electronic device having a reverse current from the output terminal to the input terminal under special conditions. The electronic device may be a diode, a triode, an electronic component comprising a plurality of electronic elements as described above. The specific type and structure of the electronic device do not constitute limitation to the embodiments of the present application as long as it probably has a reverse current.

As shown in FIG. 7, the method 700 for blocking the reverse signal of the electronic device may comprise: determining whether the electronic device satisfies the condition of having a reverse current (S710); generating an indication signal for indicating whether the electronic device is capable of having a reverse current based on a result of the determination (S720); connecting the electronic device with a load thereof, or blocking the connection of the electronic device with the load thereof, based on the indication signal.

In accordance with different electronic devices, in S710, it is feasible to determine whether the electronic device satisfies the condition of having a reverse current in different modes. Specifically, S710 may be implemented based on a predetermined condition for generating the reverse current in the electronic device.

In the case where the electronic device is a diode, whether the diode satisfies the condition of having a reverse current or not can be determined according to at least one of the reverse voltage and temperature of the diode. Specifically, the S710 may include: detecting at least one of the reverse voltage and the temperature of the diode; determining or estimating the reverse current thereof according to the relation table among the reverse voltage, the temperature of the diode and the reverse current thereof; and determining that the diode satisfies the condition of having a reverse current when the determined or estimated reverse current is greater than the preset current threshold value.

In the case where the electronic device is a triode, whether the triode satisfies the condition of having a reverse current or not can be determined according to the operation state and source-drain voltage of the triode. For example, the S710 may include: determining whether a NMOS triode is in an off state; determining whether the source-drain voltage thereof is greater than zero when the NMOS triode is in the off state, determining that the NMOS triode meet the condition of having a reverse current when the source-drain voltage is greater than zero; and when the NMOS triode is not in the off state, or the source-drain voltage is not greater than zero, determining that the NMOS triode does not meet the condition of having a reverse current.

Further, in the switch apparatus 400 shown in FIG. 4, whether the first switch S11 satisfies the condition of having a reverse current or not can be determined according to the operation state of the first switch S11. For example, when the first switch S11 is closed, it is determined that the first switch S11 does not meet the condition of having the reverse current; when the first switch S11 is opened, it is determined that the first switch S11 satisfies the condition of having a reverse current.

In S720, an indication signal indicating whether the electronic device is capable of having a reverse current or nor is generated based on the determination result in of the determination operation in S710. Specifically, when the determination result indicates that the electronic device satisfies the condition of having the reverse current, an indication signal indicating that the electronic device is capable of having the reverse current is generated; when the determination result indicates that the electronic device does not meet the condition of having a reverse current, an indication signal indicating that the electronic device is not capable of having the reverse current is generated. Alternatively, an indication signal indicating that the electronic device does not have the reverse current may also be generated in all the cases except that the determination result indicates that the electronic device satisfies the condition of having a reverse current.

In S730, the electronic device and the load thereof are connected or the connection between the electronic device and the load thereof is blocked based on the indication signal. For example, the electronic device and the load thereof may be connected, when the indication signal indicates that the electronic device is not capable of having a reverse current; and the connection between the electronic device and the load thereof may be blocked, when the indication signal indicating the electronic device is capable of having the reverse current.

A switch or a variable resistor may be used for implementing the connection between the electronic device and the load thereof or blocking of the connection. As an example, when the indication signal indicates that the electronic device is not capable of having a reverse current, the variable resistor is controlled to have a minimum resistance value (e.g., 0 ohm), so as to connect the electronic device and the load thereof; when the indication signal indicates that electronic device is capable of having a reverse current, the variable resistor is controlled to have a maximum resistance value, thus approximately forms an open circuit between the electronic device and the load thereof to significantly reduce or eliminate the reverse current. When the switch is used for implementing the connection between the electronic device and the load thereof or the blocking of the connection, a reverse connection between the switch and the electronic device may be performed, and the specific connection mode may be found in the description in conjunction with FIG. 3.

Moreover, in practice, the method 700 for blocking the reverse signal of the electrode device may be independently implemented according to different needs of different electronic devices. For example, as for the switch apparatus shown in FIG. 4, the method for blocking the reverse signal of the electrode device according to the embodiment of the present application may be implemented specific to the first switch S11 and the second switch S21 respectively.

The method for blocking the reverse signal of the electrode device according to the embodiment of the present application can effectively block the reverse current and the reverse voltage in the electronic device, in order to ensure normal operation of the electronic device and protect the electronic device per se. Further, as shown in FIG. 3, an ordinary triode can be conveniently used for blocking the reverse current in the electronic device and this solution is simple and of low cost.

In the various examples described herein, references are made to triodes. It will be understood that such triodes can include transistors such as field-effect transistors (FETs). Such FETs can include, for example, MOSFET devices and/or transistors implemented in other process technologies. Other types of transistors can be utilized to implement one or more features of the present disclosure.

Those skilled in the art can clearly understand, for the convenience and simplicity of description, that the specific implementation of the method embodiments may refer to the corresponding process in the above-described product embodiments.

Those ordinarily skilled in the art may be aware that, the devices and algorithm steps of all the examples as described by the embodiments disclosed in the present application can be implemented by electronic hardware, or a combination of software and electronic hardware. A person skilled in the art can implement the described function by using different methods for each specific application, but this implementation should not be deemed as going beyond the scope of this invention.

The above described are only specific embodiments of the present application, but the scope of the present application is not limited thereto, and any person skilled in the art, within the technical scope disclosed by the present application, can easily conceive that variations or replacements should be covered within the protection scope of the present application.

1. A blocking system for an electronic device, the blocking system comprising:
a determining unit configured to generate an indication signal indicative of a condition associated with an undesirable current in the electronic device; and
a blocking unit in communication with the determining unit, the blocking unit configured to be coupled to a terminal of the electronic device, the blocking unit further configured to inhibit or reduce passage of the undesirable current in the electronic device based on the indication signal.

2. The blocking system of claim 1 wherein the undesirable current includes a reverse current.

3. The blocking system of claim 2 wherein the terminal includes an output terminal of the electronic device.

4. The blocking system of claim 3 wherein the blocking unit is capable of being implemented between the output terminal of the electronic device and a load associated with the electronic device.

5. The blocking system of claim 3 wherein the condition associated with an undesirable current includes a condition where the electronic device is capable of having the reverse current.

6. The blocking system of claim 5 wherein the electronic device includes a switching device.

7. The blocking system of claim 6 wherein the switching device is a switching transistor having a gate, a drain, and a source, the switching transistor configured to be in an ON state or an OFF state based on a switching signal provided to the gate.

8. The blocking system of claim 7 wherein the source of the switching transistor is the output terminal of the electronic device, such that the switching transistor is configured to allow passage of a forward current to the load when the switching transistor is in the ON state.

9. The blocking system of claim 8 wherein the switching transistor is capable of having the reverse current when a voltage at the source is higher than a voltage at the drain when the switching transistor is in the OFF state.

10. The blocking system of claim 9 wherein the blocking unit includes a blocking transistor having a gate, a drain, and a source, the blocking transistor configured to be in an ON state or an OFF state based on a switching signal provided to its gate, the blocking transistor implemented such that the source of the blocking transistor is coupled to the source of the switching transistor and the drain of the blocking transistor is coupled to the load.

11. The blocking system of claim 10 wherein the gate of the blocking transistor is configured to receive the indication signal or a control signal representative of the indication signal.

12. The blocking system of claim 11 wherein the indication signal or the control signal representative of the indication signal is configured to turn the blocking transistor ON when the switching transistor is in its ON state.

13. The blocking system of claim 11 wherein the indication signal or the control signal representative of the indication signal is configured to turn the blocking transistor OFF when the switching transistor is in its OFF state and its source voltage is higher than its drain voltage.

14. The blocking system of claim 13 wherein the blocking transistor includes a parasitic diode property with a cathode of the parasitic diode being coupled to the load to further inhibit flow of current from the load into the switching transistor.

15. A method for blocking reverse current in an electronic device, the method comprising:
determining whether a condition exists for a reverse current in the electronic device;
generating an indication signal based on the condition; and
operating a blocking unit based on the indication signal, the blocking unit coupled to a terminal of the electronic device, the blocking unit further configured to inhibit or reduce passage of the reverse current in the electronic device if the indication signal indicates the reverse current condition.

16. (canceled)

17. (canceled)

18. (canceled)

19. (canceled)

20. (canceled)

21. (canceled)

22. (canceled)

23. (canceled)

24. (canceled)

25. A portable electronic apparatus comprising:
a power supply component configured to provide a plurality of voltages;
a load module configured to utilize one or more of the voltages provided by the power supply component; and
a switching circuit implemented between the power supply component and the load module, the switching circuit including a first switch having an input and an output, the input coupled to the power supply component, the output coupled to the load module, the first switch configured to be in an ON state or an OFF state, the switching circuit further including a blocking switch implemented between the output of the first switch and the load module, the blocking switch configured to receive an indication signal indicative of a condition associated with an undesirable current in the first switch, the blocking switch further configured to inhibit or reduce passage of the undesirable current in the first switch based on the indication signal.

26. The portable electronic apparatus of claim 25 wherein the switching circuit further includes a second switch implemented to be parallel with the first switch, the second switch having an input coupled to the power supply component and an output coupled to the load module, the second switch configured to be in an ON state or an OFF state, the switching circuit configured to allow passage of first or second voltage from the power supply component to the load module.

27. The portable electronic device of claim 26 wherein the portable electronic device is a wireless device having a power amplifier module as the load module, the power amplifier module configured to operate with at least the first voltage of the second voltage.

28. The portable electronic device of claim 26 wherein the load module includes an LED module configured to operate with at least the first voltage of the second voltage.
